(19) United States
(12) Patent Application Publication
(10) Pub. No.: US 2007/0030736 A1
(43) Pub. Date: Feb. 8, 2007

(54) Variable source resistor for flash memory

(76) Inventors: Fabiano Fontana, San Jose, CA (US); Steven Fong, Santa Clara, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/196,093

(22) Filed: Aug. 3, 2005

(51) Int. Cl. G11C 16/04; G11C 11/34

(52) U.S. Cl. 365/185.18

(57) ABSTRACT

In one embodiment of the invention, a flash memory is provided that includes: a plurality of flash memory cells sharing a common drain node and a common source node; and a current source that controls the current into the common source node.

### TECHNICAL FIELD

The present invention relates generally to flash memory, and more particularly to limiting bit line current of flash memory during programming.

### BACKGROUND

Flash memory differs from other types of electrically erasable memories in that one cannot arbitrarily erase individual bits or words in flash memory in an efficient manner. Instead, memory cells in flash memories are organized into sectors such that all data within a sector must be erased (or “flashed”)—one cannot select individual bits or bytes within a flash sector for erasure. Although flash memory has a number of variations such as whether it is NAND-based or NOR-based, a number of features are common to the erasure process for flash memories.

For example, because flash memories erase all the memory cells in a sector during each erase cycle, there is a possibility that some of the memory cells may have been “over-erased” such that an over-erased cell has an undesirable threshold voltage (Vt). Thus, as part of each erasure cycle, a programming step (which may be denoted as a self-convergent programming step) occurs that corrects for any over-erased cells. For example, FIG. 1 illustrates a sector 100 of flash memory cells (for illustration clarity, only a single flash memory cell 105 is shown). Each memory cell 105 shares a common drain node D and a source node S. However, a word line 110 is unique to each memory cell. A charge pump 120 charges the drain node D to the desired voltages during the programming stages. During erasure using, for example, Fowler-Nordheim tunneling, drain node D is effectively tri-stated.

There is a limit to the amount of current that can be drawn through node D from charge pump 120 before the voltage at node D drops to undesirable levels during programming events. However, during programming steps such as self-convergent programming, a transistor 130 coupled to source node S is turned on such that current may flow through memory cells 105 that have been over-erased. Transistor 130 thus acts as a switch. In turn, the current flow from activation of transistor 130 may pull the drain voltage at node D too low because charge pump 120 cannot meet the current demand while still maintaining the desired voltage at node D. Thus, it is conventional to couple node S to transistor 130 through a resistor R to limit the current flow from charge pump 120 in cyclical events such as the self-convergent programming (SCP) step.

The inclusion of resistor R, however, creates a number of problems. For example, because the resistance of resistor R is fixed, this resistance must be properly chosen. If the resistance is too low, the current is not properly limited such that the voltage provided by charge pump 120 may collapse. If the resistance is too high, however, the current is limited too much such that the effectiveness of the SCP step is reduced, thereby leaving over-erased memory cells uncorrected. In addition, an overly-high resistance increases the required time for SCP processing to undesirable levels. But selection of the proper resistance to avoid these issues is problematic because of inevitable semiconductor process variations, temperate effects, and other variables.

Accordingly, there is a need in the art for improved memory flash architectures that appropriately limit current during programming of the memory cells.

### SUMMARY

In accordance with an embodiment of the invention, a flash memory is provided that includes: a plurality of flash memory cells sharing a common drain node and a common source node; and a current source that controls the current into the common source node.

In accordance with another embodiment of the invention, a method of controlling current during flash memory programming events is provided in a flash memory having a plurality of flash memory cells sharing a common drain node and a common source node, the common source node being coupled to a transistor adapted to control a current through the common source node, the method comprising: generating a reference voltage using a reference circuit; and biasing the transistor with the reference voltage to control the current through the common source node.

In accordance with another embodiment of the invention, a flash memory within an integrated circuit is provided that includes: a plurality of flash memory cells sharing a common drain node and a common source node; a charge pump coupled to the common drain node and adapted to charge the common drain node to a desired voltage; and a current source adapted to provide a current into the common source node and through the common drain node to the charge pump, the current source being adapted to be substantially insensitive to semiconductor process variations and temperature variations.

### BRIEF DESCRIPTION OF THE DRAWINGS

FIG. 1 is a circuit diagram of a conventional flash memory sector.

FIG. 2 is a circuit diagram of a flash memory sector in accordance with an embodiment of the invention.

FIG. 3 is illustrates the I-V characteristics for the flash memories of FIGS. 1 and 2 for fast, typical, and slow semiconductor process variations.

FIG. 4 illustrates an exemplary implementation of the current source of FIG. 2 in accordance with an embodiment of the invention.

Use of the same reference symbols in different figures indicates similar or identical items.

### DETAILED DESCRIPTION

Reference will now be made in detail to one or more embodiments of the invention. While the invention will be described with respect to these embodiments, it should be understood that the invention is not limited to any particular embodiment. On the contrary, the invention includes alternatives, modifications, and equivalents as may come within the spirit and scope of the appended claims. Furthermore, in the following description, numerous specific details are set forth to provide a thorough understanding of the invention. The invention may be practiced without some or all of these specific details. In other instances, well-known structures and principles of operation have not been described in detail to avoid obscuring the invention.

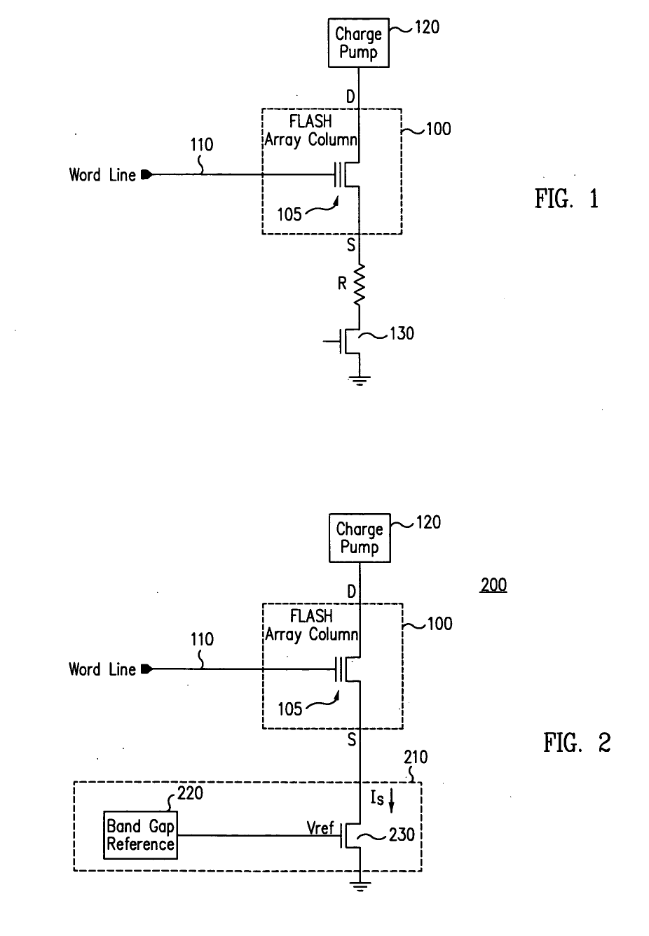

An improved flash memory architecture is disclosed that avoids the problems of limiting current draw from a flash memory charge pump using a fixed resistance. An exemplary embodiment for such a flash memory 200 is illustrated in FIG. 2. Flash memory cells 105 are organized in a sector 100 as discussed with respect to FIG. 1. For illustration clarity, only a single flash memory cell 105 is illustrated within sector 100. Flash memory cells 105 may be either NAND-based or NOR-based flash memory cells as known in the art. Flash memory cells 105 share a common drain node D and a common source node S but have unique word lines 110. Drain node D forms a common bit line or column line for flash memory cells 105. As discussed above, well-known structures such as sense paths coupled to common drain node D are not illustrated to avoid obscuring the disclosed innovations. During cyclical events such as self-convergent programming steps, current through charge pump 120 may be too great such that a voltage at common drain node D for memory cells 105 is pulled too low. The current through common drain node D is supplied by common source node S. In the prior art, current into node S is limited by a fixed resistance as discussed with respect to FIG. 1. However, the choice of the proper fixed resistance value is problematic in view of inevitable process variations and other variations such as temperature and voltage changes. These difficulties are solved by using a current source 210 that controls the current into node S. Current source 210 includes a transistor such as FET 230 having a gate voltage Vref controlled by a reference circuit such as band gap reference circuit 220. As known in the arts, band gap reference circuit 220 can maintain the stability of Vref despite the presence of semiconductor process variations, temperature variations, and other variables. Thus, a current Is through transistor 230 is resistant to these variations and maintained substantially constant.

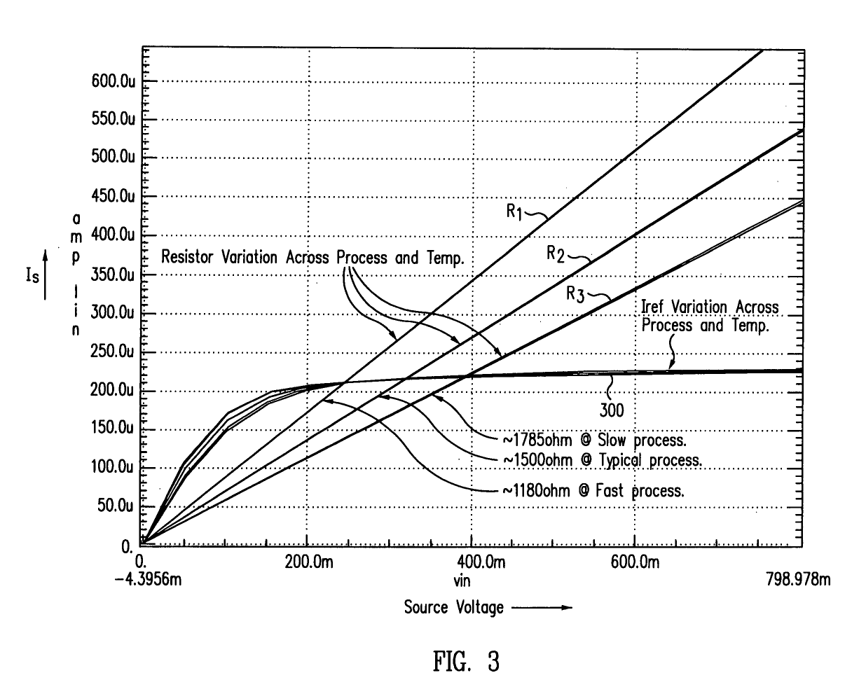

The advantages of a current-source-based approach for limiting current during SCP and other programming events vs. a fixed-resistance-based approach of the prior art may be better understood with reference to FIG. 3. FIG. 3 illustrates the source current Is as a function of source node voltage for fast (˜1180Ω), typical (˜1500Ω), and slow (˜1785Ω) semiconductor processes. The I-V characteristic for prior art resistor R of FIG. 1 is illustrated as lines R1, R2, and R3, corresponding to the fast, typical, and slow semiconductor processes, respectively. As can be seen from inspection of FIG. 3, the source current Is varies considerably depending upon the semiconductor process at typical operating voltage values for the fixed resistance approach. For example, at a source voltage of 600 mV, there is a 150 μA variation in Is between the slow and fast semiconductor process extremes (lines R1 and R3). However, the source current variation for current source 210 (represented by lines 300) is negligible at this voltage with respect to these same semiconductor process variations. Indeed, if current source 210 is biased above 200 mV, there is essentially no variation in Is for the current source approach as compared to the substantial current variation for the fixed resistance approach. Moreover, referring back to FIG. 2, at a relatively low source node voltage (such as approximately 0.3 V or lower), current Is is not limited to the extent that it would be should a fixed resistance be implemented. In this fashion, programming acts such as SCP operate faster and more effectively at lower source voltages due to the replacement of a fixed resistance with current source 210. Furthermore, even at higher source voltages (such as approximately 0.3 V or higher), the current Is is limited by current source 210 such that charge pump 120 may maintain the proper voltage at common drain node D. In contrast, a higher source voltage forces a higher current through a fixed resistance such that the danger of charge pump collapse is not eliminated.

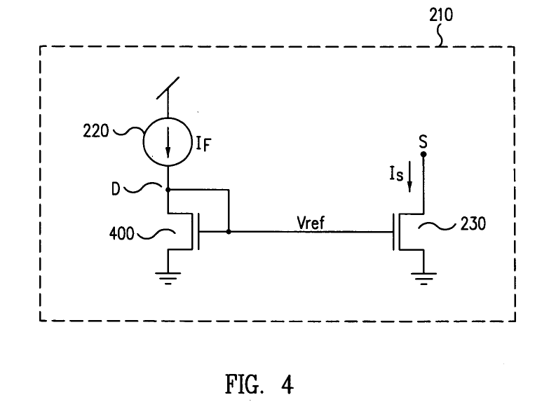

Further details for an exemplary implementation of current source 210 are illustrated in FIG. 4. Band gap reference 220 drives a current IF through a drain node D of a transistor 400 coupled in current mirror configuration to the gate of transistor 230. Based upon the relative channel dimensions for transistors 400 and 230, the current Is through transistor 230 will be proportional to or equal to current IF. It will be appreciated that other types of current sources besides a band gap reference 220 may be used that are resistant to changes in semiconductor process variations and other variations such as changes in temperature and operating voltage. Because current IF will be resistant to these variables, so is source current Is. In turn, the current through charge pump 120 (FIG. 2) will be controlled to desirable levels during programming events.

The above-described embodiments of the present invention are merely meant to be illustrative and not limiting. For example, embodiments of the disclosed flash memory may be integrated with programmable logic devices to, for example, store corresponding configuration signals. It will thus be obvious to those skilled in the art that various changes and modifications may be made without departing from this invention in its broader aspects. Accordingly, the appended claims encompass all such changes and modifications as fall within the true spirit and scope of this invention.

We claim:

1. A flash memory, comprising:
a plurality of flash memory cells sharing a common drain node and a common source node; and
a current source adapted to control a current through the common source node.

2. The flash memory of claim 1, wherein the current source comprises a transistor coupled to the common source node.

3. The flash memory of claim 1, wherein the current source comprises a band gap reference circuit that controls a reference voltage supplied to a gate of a transistor coupled to the common source node to thereby control the current through the common source node.

4. The flash memory of claim 3, wherein the band gap reference circuit drives a reference current into a current-mirror configured transistor to produce the reference voltage.

5. The flash memory of claim 1, wherein the flash memory cells are NOR-based memory cells.

6. The flash memory of claim 1, wherein the flash memory cells are NAND-based memory cells.

7. The flash memory of claim 1, further comprising:
a charge pump configured to maintain a desired voltage at the common drain node.

8. The flash memory of claim 1, wherein each flash memory cell has a gate controlled by a unique word line.

9. The flash memory of claim 1, wherein the common drain node forms a bit line for the plurality of flash memory cells.

10. The flash memory of claim 1, wherein the plurality of flash memory cells form a sector of flash memory cells.

11. A method of controlling current during flash memory programming events in a flash memory having a plurality of flash memory cells sharing a common drain node and a common source node, the common source node being coupled to a transistor adapted to control a current through the common source node, the method comprising:
generating a reference voltage using a reference circuit; and
biasing the transistor with the reference voltage to control the current through the common source node.

12. The method of claim 11, wherein the generating the reference voltage act comprises using a band gap reference circuit.

13. The method of claim 11, further comprising:
charging the common drain node using a charge pump, wherein the control of the current through the transistor prevents collapse of the common drain node charge.

14. The method of claim 12, further comprising:
programming the plurality of flash memory cells during the charging of the common drain node.

15. The method of claim 11, further comprising:
correcting for any over-erasure of the plurality of flash memory cells during the control of the current through the transistor.

16. Within an integrated circuit, a flash memory comprising:
a plurality of flash memory cells sharing a common drain node and a common source node;
a charge pump coupled to the common drain node and adapted to charge the common drain node to a desired voltage; and
a current source adapted to provide a current into the common source node and through the common drain node to the charge pump, the current source being adapted to be substantially insensitive to semiconductor process variations and temperature variations, whereby excessive charge does not pass through the common drain node into the charge pump during programming events such that the common drain node is maintained at the desired voltage.

17. The flash memory of claim 16, wherein the current source includes a band gap reference circuit.

18. The flash memory of claim 16, wherein the flash memory is integrated within a programmable logic device.

19. The flash memory of claim 18, wherein the flash memory is adapted to store configuration signals for the programmable logic device.

20. The flash memory of claim 19, wherein the programmable logic device is a field programmable gate array.
